(19) United States
(12) Patent Application Publication
(10) Pub. No.: US 2002/0020844 A1
(43) Pub. Date: Feb. 21, 2002

(54) Structural improvement of a LED

(75) Inventor: Frank Liu, Hsin-Tien City (TW)

Correspondence Address: DOUGHERTY & TROXELL, SUITE 1404, 5205 LEESBURG PIKE, FALLS CHURCH, VA, 22041, US

(73) Assignee: LEDTECH ELECTRONICS CORPORATION

(21) Appl. No.: 09/930,206

(22) Filed: Aug. 16, 2001

(30) Foreign Application Priority Data
Aug. 17, 2000 (TW) 89214267

(51) Int. Cl. H01L 33/00; H01L 31/12; H01L 27/15

(52) U.S. Cl. 257/81

(57) ABSTRACT

A structural improvement of a LED. It constructed a third leg between the first and second leg. A chip resistor is stick between the third leg and the first leg by using electric conducting resin, also a LED dice is placed on the top of the third leg, and it is connected with the first leg by using wire. The above description can be sealed in a gum body and be produced by machine. This would decrease the budget and achieve the goal of not enlarging the LED.

### FIELD OF THE INVENTION

This invention relates to a structural improvement of an LED (Light-emitting diode), especially the structure of an LED used under “high voltage”.

### BACKGROUND OF THE INVENTION

While using the traditional LED people use under high voltage, a chip resistor has to be welded on one of the legs of the LED (refer to FIG. 1). The disadvantage of this kind of structure would be: (1) it is a waste of time while producing these, the budget is also higher, (2) it has a larger size; (3) the outfit does not look fine.

### SUMMARY OF THE INVENTION

An object of the present invention is to produce a kind of structure that place the chip resistor in the gum body, and this structure can easily be produced in huge amounts.

Another object of this invention is to place another leg between the two original legs. SMT chip resistors, LED Dices and wires are places between the three legs. These three legs can be hold fixed at the same time, which provides the usage of holding the legs fixed by using gum.

Another object of this invention is to add a chip resistor but not to enlarge the size of the LED. Not only the chip resistor can be hold fixed well, but also under the condition of the size limit, this kind of LED can more likely to be chosen by the customers.

This present invention still looks perfectly fine.

Further objects and advantages of the invention will be brought out in the following portions of the specification, wherein the detailed description is for the purpose of fully disclosing preferred embodiments of the invention with,out placing limitations thereon.

### BRIEF DESCRIPTION OF THE DRAWING

The invention will be more fully understood by reference to the following drawings which are for illustrative purposes only:

FIG. 1: is a structure of a prior art LED.

Fig. 2: is a structure of the present invention.

### DETAILED DESCRIPTION OF THE PREFERRED EMBODIMENT

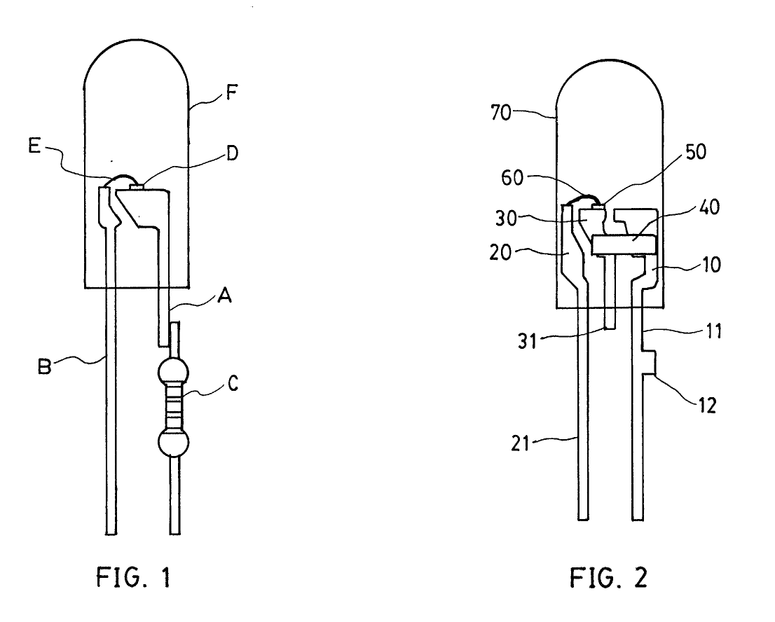

Referring to FIG. 1, this is the structure of a traditional high voltage LED, it contains two legs A and B, a chip resistor C, a LED Dice D, wire E and gum body F. The chip resistor C is weld to the leg A.

Referring to FIG. 2, this is the structure of this invention, it contains three legs, the first leg 10, second leg 20 and the third leg 30, and it also contains a SMT chip resistor 40, a LED Dice 50, wire 60 and the gum body 70.

Due to the structure, the top of the first leg 10, the second leg 20, the third leg 30, and also the chip resistor 40, LED Dice 50, wire 60 are all sealed in the gum body 70.

The chip resistor 40 is stick to the upper side of the first leg 10 and the third leg by using electrical conducting resin. The LED Dice 50 is stick to the top of the third leg 30 by using electrical conducting resin. Wire 60 connects the second leg 20 and the LED Dice 50. The bottom part 11, 21, 31 of the leg 10, 20 and 30 can be attached, so the top part or the whole structure can be sealed in the gum body 70.

At a reasonable height below the first leg 10 and the third leg 30 can construct a brick 12, so the height of the LED can be uniformed while plugging the LED on the bread board.

By concluding the above descriptions, this case has added a leg. Also by sticking the chip resistor and make it available for attaching, this product solved the problem that the traditional LED's could not solve.

The foregoing description is provided for illustrative purposes only and should not be construed as limiting this invention, the scope of which is defined solely by the appended claims.

What is claimed is:

1. A structural improvement of a LED, comprising three legs, a chip resistor, a LED Dice, wire and the gum body. The specialty is to place a chip resistor between the first leg and the third leg. A LED Dice is placed on the top of the third leg, and also the LED Dice is connected to the second leg by using wire. The whole product ends up being a LED that can be used under high voltage.
